(19) United States
(12) Patent Application Publication
(10) Pub. No.: US 2021/0359177 A1
(43) Pub. Date: Nov. 18, 2021

(54) LED lamp and method for increasing lumens thereof

(71) Applicant: Jiangsu New Cloud China Photoelectric Technology Co., LTD, RuDong County (CN)

(72) Inventor: LI-CHEN LIN, Taipei City (TW)

(21) Appl. No.: 17/278,459

(22) PCT Filed: Sep. 28, 2018
(86) PCT No.: PCT/CN2018/108286

§ 371 Date: Mar. 22, 2021

(51) Int. Cl. H01L 33/60; H01L 33/50

(52) U.S. Cl. CPC H01L 33/60; H01L 33/502

(57) ABSTRACT

The present invention provides a light-emitting diode lamp with increased lumens. The increased lumens to the LED lamp consists of a substrate body, at least one reflective cup, the reflective cup is disposed on the substrate body, at least one light-emitting element disposed on the substrate body and electrically connected to the substrate body, with at least one fluorescent unit, wherein, the fluorescent unit further includes a top layer of a light-emitting element, a side layer of a light-emitting element, a reflective cup surface layer and a substrate body surface layer. Light-emitting diode lamp increases the brightness. It is superior to the currently known light-emitting diode lamp.

### FIELD OF THE INVENTION

The invention relates to a LED lamp for increasing lumens. In particular, it is about a method of increasing lumens by LED lights.

### BACKGROUND OF THE INVENTION

In recent years, the use of energy-saving light sources has begun to be widely used in order to protect the earth and the desire for sustainable survival. Among them, LED lights that require low electrical energy and can provide sufficient brightness have grown fastest.

Comparing LED lamps with traditional light sources, LED lamps have the advantages of small size, power saving, good luminous efficiency, long life, fast operation response, and no heat radiation and mercury and other toxic substances pollution. Therefore, in recent years, LED The application of the lamp has been extremely extensive. In the past, the brightness of LED lamps has not been able to replace traditional lighting sources. However, the conversion technology is constantly improving. At present, high-power light-emitting diodes with high lighting brightness have been developed, whose refractive index replaces traditional lighting sources. However, the traditional use of light-emitting diode lamps still cannot effectively improve the overall light extraction efficiency.

The conventional LED lamp package structure usually includes a substrate, an electrode on the substrate, a light emitting diode chip carried on the substrate and electrically connected to the electrode, and a package body covering the light emitting diode chip on the substrate. In order to improve the light-emitting characteristics of the light-emitting diode chip, fluorescent particles are usually disposed in the light-emitting diode package structure, as shown in FIGS. 1 and 2, where the components in the first figure are as follows: substrate body 101 , LED component 102, surrounding reflective frame 105, packaging gel 110, silicone 120, silicone 130, fluorescent particles 131. Among them, the elements in FIG. 2 are as follows: the substrate body 201, the LED component 202, the surrounding reflective frame 205, the silicone 230, and the fluorescent particles 231. Fluorescent particles are usually coated on the light-emitting surface of the package by dispensing or spraying. However, due to the randomness of spraying, the distribution of fluorescent particles is likely to be uneven; or mixed in the packaging material before the package is formed. When the packaging material is solidified, the fluorescent particles suspended in the packaging material will be deposited, or too many fluorescent particles will cause the light generated by the fluorescent particles to be blocked by other fluorescent particles, resulting in a reduction in luminous efficiency, or the cured package The fluorescent particles are not uniformly distributed, thereby affecting the final light-emitting effect of the light-emitting diode package structure.

Therefore, how to manufacture low-cost LED lamps and the problem of excessively high color temperature produced by them, and avoid the phenomenon of insufficient brightness, that is, to increase the brightness of the unit, is still an industry demand that the industry is eager to improve.

### SUMMARY OF THE IVENTION

In view of the above-mentioned background of the invention, in order to meet the needs of the industry, the present invention provides an LED lamp to solve the problems faced by the industry, and at the same time improve the brightness of the LED lamp.

According to one objective of the present invention, a LED lamp, comprising: a substrate body; a reflecting cup, said reflecting cup is disposed on said substrate body and said inclined surface of said reflecting cup and said substrate body included angle R is between 15 degrees and 80 degrees; a LED component, said LED component is disposed on said substrate body and is electrically connected to said substrate body; and a fluorescent unit, said fluorescent unit is a mixed layer of fluorescent particles and adhesives, wherein said fluorescent unit further includes a top layer of LED component, a side layer of LED component, a surface layer of beveled reflecting cup, and a surface layer of substrate body; said top layer of LED component is disposed on the side of said LED component away from the substrate body, and the thickness of said top layer of LED component is between 1 nanometer and 10 cm; said side layer of LED component is disposed on said LED component and said substrate body is vertical, and the thickness of said side layer of LED component is between 1 nanometer and 10 cm; said surface layer of beveled reflecting cup is disposed on the inclined surface of said reflecting cup, and the thickness of said surface layer of beveled reflecting cup is above 1 nanometer; said surface layer of said substrate body is disposed on the surface of said substrate body between said LED component and said reflecting cup, and the thickness of said surface layer of substrate body is between 1 nanometer and 10 cm; wherein, the combined thickness of said side layer of LED component and said surface layer of beveled reflecting cup is smaller than the distance between the vertical surface of said LED component and said substrate body and the inclined surface of the reflecting cup; Wherein, said surface layer of substrate body is smaller than the distance between the side of said LED component away from said substrate body and the surface of said substrate body; said surface layer of beveled reflecting cup covers the inclined surface of said reflecting cup, wherein, the fluorescent particles of said surface layer of beveled reflecting cup cover the area of the inclined surface of said reflecting cup by more than 50%.

One object of the present invention is to provide a LED lamp, comprising: a substrate body; a reflecting cup, said reflecting cup is disposed on said substrate body and said inclined surface of said reflecting cup and said substrate body included angle R is between 15 degrees and 80 degrees; a LED component, said LED component is disposed on said substrate body and is electrically connected to said substrate body; and a fluorescent unit, said fluorescent unit is a mixed layer of fluorescent particles and adhesives, wherein said fluorescent unit further includes a top layer of LED component, a side layer of LED component, a surface layer of beveled reflecting cup, a surface layer of substrate body, and the surface layer of top reflecting cup; said top layer of LED component is disposed on the side of said LED component away from the substrate body, and the thickness of said top layer of LED component is between 1 nanometer and 10 cm; said side layer of LED component is disposed on said LED component and said substrate body is vertical, and the thickness of said side layer of LED component is between 1 nanometer and 10 cm; said surface layer of beveled reflecting cup is disposed on the inclined surface of said reflecting cup, and the thickness of said surface layer of beveled reflecting cup is above 1 nanometer; said surface layer of said substrate body is disposed on the surface of said substrate body between said LED component and said reflecting cup, and the thickness of said surface layer of substrate body is between 1 nanometer and 10 cm; the surface layer of top reflecting cup is disposed on the top of the reflecting cup, and the thickness of the surface layer of top reflecting cup is above 1 nanometer; wherein, the combined thickness of said side layer of LED component and said surface layer of beveled reflecting cup is smaller than the distance between the vertical surface of said LED component and said substrate body and the inclined surface of the reflecting cup; Wherein, said surface layer of substrate body is smaller than the distance between the side of said LED component away from said substrate body and the surface of said substrate body; said surface layer of beveled reflecting cup covers the inclined surface of said reflecting cup, wherein, the fluorescent particles of said surface layer of beveled reflecting cup cover the area of the inclined surface of said reflecting cup by more than 50%.

One object of the present invention is to provide a LED lamp, comprising: a reflecting cup; a LED component, said reflecting cup is disposed on said substrate body and said inclined surface of said reflecting cup and the bottom end of the reflecting cup included angle R is between 15 degrees and 80 degrees; a fluorescent unit, said fluorescent unit is a mixed layer of fluorescent particles and adhesives, wherein said fluorescent unit further includes a top layer of LED component, a side layer of LED component, a surface layer of beveled reflecting cup, and the surface layer of top reflecting cup; said top layer of LED component is disposed on the side of said LED component away from the bottom end of the reflecting cup, and the thickness of said top layer of LED component is between 1 nanometer and 10 cm; said side layer of LED component is disposed on said LED component and said substrate body is vertical, and the thickness of said side layer of LED component is between 1 nanometer and 10 cm; said surface layer of beveled reflecting cup is disposed on the inclined surface of said reflecting cup, and the thickness of said surface layer of beveled reflecting cup is above 1 nanometer; the surface layer of top reflecting cup is disposed on the top of the reflecting cup, and the thickness of the surface layer of top reflecting cup is above 1 nanometer; wherein, the combined thickness of said side layer of LED component and said surface layer of beveled reflecting cup is smaller than the distance between the vertical surface of said LED component and the bottom end of the reflecting cup and the inclined surface of the reflecting cup; wherein, said surface layer of substrate body is smaller than the distance between the side of said LED component away from said substrate body and the surface of said substrate body; said surface layer of beveled reflecting cup covers the inclined surface of said reflecting cup, wherein, the fluorescent particles of said surface layer of beveled reflecting cup cover the area of the inclined surface of said reflecting cup by more than 50%; and a package unit, said package unit is silicone and covers said LED component, said reflecting cup, and said fluorescent unit.

One object of the present invention is to provide a method for increasing the lumens of the LED lamp, comprising: providing a reflecting cup, said reflecting cup is disposed on a substrate body and said inclined surface of said reflecting cup and said substrate body included angle R is between 15 degrees and 80 degrees; a LED component, said LED component is disposed on the substrate body and is electrically connected to said substrate body; and providing a fluorescent unit, said fluorescent unit is a mixed layer of fluorescent particles and adhesives, wherein said fluorescent unit further includes a top layer of LED component, a side layer of LED component, a surface layer of beveled reflecting cup, and a surface layer of substrate body; said top layer of LED component is disposed on the side of said LED component away from the substrate body, and the thickness of said top layer of LED component is between 1 nanometer and 10 cm; said side layer of LED component is disposed on said LED component and said substrate body is vertical, and the thickness of said side layer of LED component is between 1 nanometer and 10 cm; said surface layer of beveled reflecting cup is disposed on the inclined surface of said reflecting cup, and the thickness of said surface layer of beveled reflecting cup is between 1 nanometer and 10 cm; said surface layer of said substrate body is disposed on the surface of said substrate body between said LED component and said reflecting cup, and the thickness of said surface layer of substrate body is between 1 nanometer and 10 cm; wherein, the combined thickness of said side layer of LED component and said surface layer of beveled reflecting cup is smaller than the distance between the vertical surface of said LED component and said substrate body and the inclined surface of the reflecting cup; wherein, said surface layer of substrate body is smaller than the distance between the side of said LED component away from said substrate body and the surface of said substrate body; said surface layer of beveled reflecting cup covers the inclined surface of said reflecting cup, wherein, the fluorescent particles of said surface layer of beveled reflecting cup cover the area of the inclined surface of said reflecting cup by more than 50%; performing a self-luminous process, in order to the LED element is driven to generate self-luminescence by electrical driving; and performing an excitation by the self-luminous and the fluorescent unit light process, in order to generate excitation light.

Preferably, wherein said adhesives further includes Epoxy resin, silicone, wax, paraffin hydrocarbon, ceramic powder, graphene and glass powder.

Preferably, wherein the thickness of top layer of LED component is between 1 nanometer and 1 cm.

Preferably, wherein the thickness of side layer of LED component is between 1 nanometer and 1 cm.

Preferably, wherein the thickness of said surface layer of beveled reflecting cup is between 1 nanometer and 1 cm.

Preferably, wherein the thickness of said surface layer of substrate body is between 1 nanometer and 1 cm.

Preferably, wherein, the fluorescent particles of said surface layer of beveled reflecting cup cover the area of the inclined surface of said reflecting cup by more than 50%.

Preferably, wherein the thickness of side layer of LED component is less than the thickness of top layer of LED component.

Preferably, wherein the thickness of surface layer of substrate body is less than the thickness of top layer of LED component.

Preferably, wherein LED component includes a blue chip.

Preferably, wherein the average diameter of fluorescent particles is more than 1 nanometer.

Preferably, wherein the surface layer of top reflecting cup is above 1 nanometer.

### BRIEF DESCRIPTION OF THE DRAWINGS

FIG. 1 shows a chart of an embodiment of the prior art.

FIG. 2 shows a chart of an embodiment of the prior art.

FIG. 3 shows a chart of a preferred embodiment of the present invention.

FIG. 4 shows a chart of a preferred embodiment of the present invention.

FIG. 5 shows a chart of a preferred embodiment of the present invention.

FIG. 6A shows an enlarged photo of a preferred embodiment of the present invention.

FIG. 6B shows an enlarged photo of a preferred embodiment of the present invention.

FIG. 6C shows an enlarged photo of a preferred embodiment of the present invention.

FIG. 7A shows an enlarged photo of a preferred embodiment of the present invention.

FIG. 7B shows an enlarged photo of a preferred embodiment of the present invention.

FIG. 7C shows an enlarged photo of a preferred embodiment of the present invention.

FIG. 8A shows an enlarged photo of a preferred embodiment of the present invention.

FIG. 8B shows an enlarged photo of a preferred embodiment of the present invention.

FIG. 8C shows an enlarged photo of a preferred embodiment of the present invention.

FIG. 9A shows an enlarged photo of a preferred embodiment of the present invention.

FIG. 9B shows an enlarged photo of a preferred embodiment of the present invention.

FIG. 9C shows an enlarged photo of a preferred embodiment of the present invention.

FIG. 10A shows an enlarged photo of a preferred embodiment of the present invention.

FIG. 10B shows an enlarged photo of a preferred embodiment of the present invention.

FIG. 10C shows an enlarged photo of a preferred embodiment of the present invention.

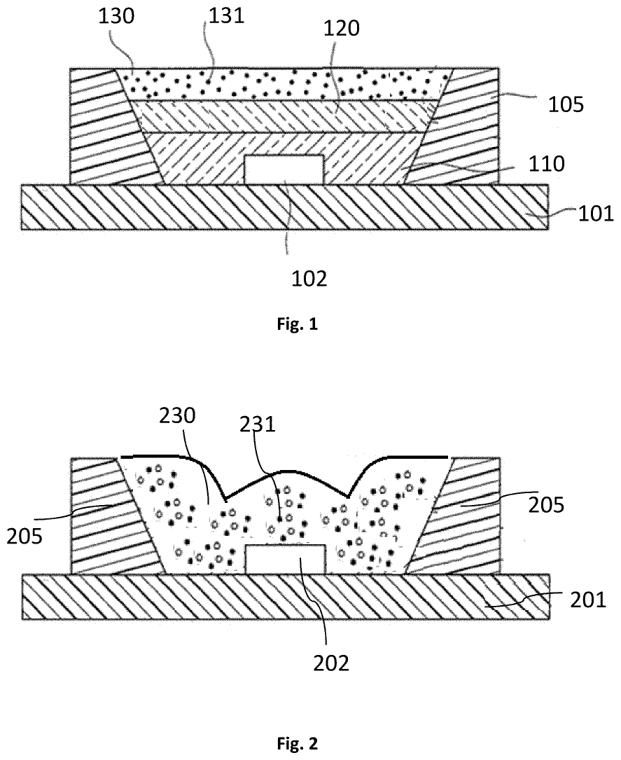

### DETAILED DESCRIPTION OF THE INVENTION

Reference will now be made in details to specific embodiment of the present invention. Examples of these embodiments are illustrated in the accompanying drawings. While the invention will be described in conjunction with these specific embodiments, it will be understood that the intent is not to limit the invention to these embodiments. In fact, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without at least one of these specific details. In other instances, the well-known portions are less or not described in detail in order not to obscure the present invention.

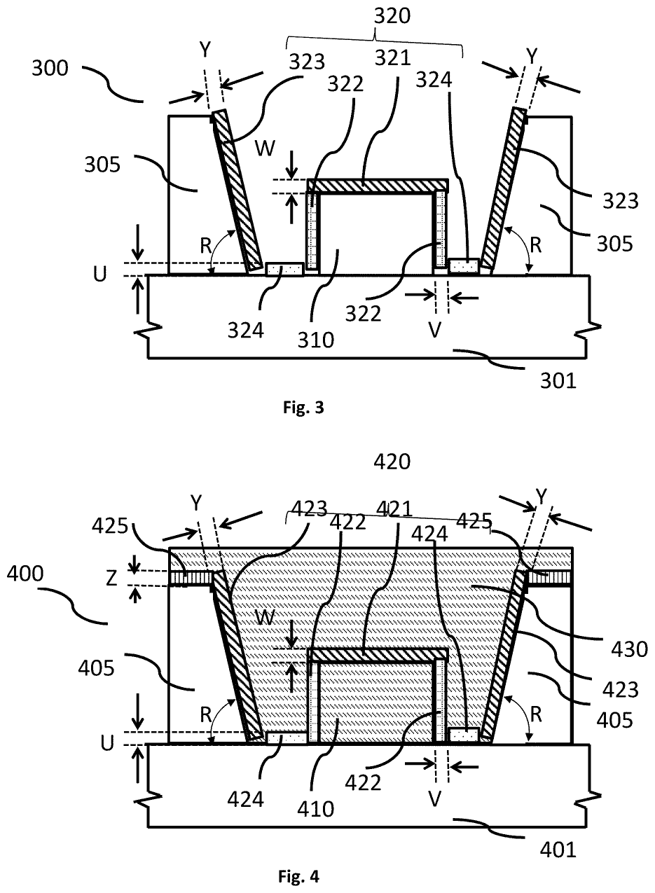

According to a preferred embodiment of the present invention, as shown in FIG. 3, a LED lamp 300 is disclosed. The LED lamp 300 comprises: a substrate body 301; at least one reflecting cup 305. The reflecting cup 305 is disposed on the substrate body 301 and the inclined surface of the reflecting cup 305 and the substrate body 301 included angle R is between 15 degrees and 80 degrees; at least one LED component 310 is disposed on the substrate body 301 and is electrically connected to the substrate body 301; and a fluorescent unit 320, which is a mixed layer of fluorescent particles and adhesives. The fluorescent unit 320 further includes a top layer of LED component 321, a side layer of LED component 322, a surface layer of beveled reflecting cup 323, and a surface layer of substrate body 324; the top layer of LED component 321 is disposed on the side of LED component 310 away from the substrate body 301, and the thickness W of the top layer of LED component 321 is between 1 nanometer and 10 cm; the side layer of LED component 322 is disposed on the LED component 310 and the substrate body 301 is vertical, and the thickness V of the side layer of LED component 322 is between 1 nanometer and 10 cm; the surface layer of beveled reflecting cup 323 is disposed on the inclined surface of the reflecting cup 305, and the thickness Y of the surface layer of beveled reflecting cup 323 is above 1 nanometer; the surface layer of substrate body 324 is disposed on the surface of the substrate body 301 between the LED component 310 and the reflecting cup 305, and the thickness U of the surface layer of substrate body 324 is between 1 nanometer and 10 cm; Wherein, the side layer of LED component 322 is not connected to the surface layer of beveled reflecting cup 323; wherein, the surface layer of substrate body 324 is not higher than the top layer of LED component 321; the surface layer of beveled reflecting cup 323 covers the inclined surface of the reflecting cup 305, Wherein, the fluorescent particles of the surface layer of beveled reflecting cup 323 cover the area of the inclined surface of the reflecting cup 305 by more than 50%.

According to a preferred embodiment of the present invention, as shown in FIG. 4, a LED lamp 400 is disclosed. The LED lamp 400 comprises: a substrate body 401; at least one reflecting cup 405. The reflecting cup 405 is disposed on the substrate body 401 and the inclined surface of the reflecting cup 405 and the substrate body 401 included angle R is between 15 degrees and 80 degrees; at least one LED component 410 is disposed on the substrate body 401 and is electrically connected to the substrate body 401; and a fluorescent unit 420, which is the fluorescent unit 420 It is a mixed layer of fluorescent particles and adhesives. The fluorescent unit 420 further includes a top layer of LED component 421, a side layer of LED component 422, a surface layer of beveled reflecting cup 423, a surface layer of substrate body 424, and the surface layer of top reflecting cup 425; the top layer of LED component 421 is disposed on the side of LED component 410 away from the substrate body 401, and the thickness W of the top layer of LED component 421 is between 1 nanometer and 10 cm; the side layer of LED component 422 is disposed on the LED component 410 and the substrate body 401 is vertical, and the thickness V of the side layer of the LED component 422 is between 1 nanometer and 10 cm; the surface layer of beveled reflecting cup 423 is disposed on the inclined surface of the reflecting cup 405, and the thickness Y of the surface layer of beveled reflecting cup 423 is above 1 nanometer; the surface layer of the substrate body 424 is disposed on the surface of the substrate body 401 between the LED component 410 and the reflecting cup 405, and the thickness U of the surface layer of substrate body 424 is between 1 nanometer and 10 cm; the surface layer of top reflecting cup 425 is disposed on the top of the reflecting cup 405, and the thickness Z of the surface layer of top reflecting cup 425 is above 1 nanometer; Wherein, the side layer of LED component 422 is not connected to the surface layer of beveled reflecting cup 423; wherein, the surface layer of substrate body 424 is not higher than the top layer of LED component 421; the surface layer of beveled reflecting cup 423 covers the inclined surface of the reflecting cup 405, Wherein, the fluorescent particles of the surface layer of beveled reflecting cup 423 cover the area of the inclined surface of the reflecting cup 405 by more than 50%; at least one package unit 430 is silicone that covers the LED component 410, the reflecting cup 405, and the fluorescent unit 420.

Furthermore, the surface layer of top reflecting cup 425 and the package unit 430 are used to increase the brightness of the LED lamp 400 described above.

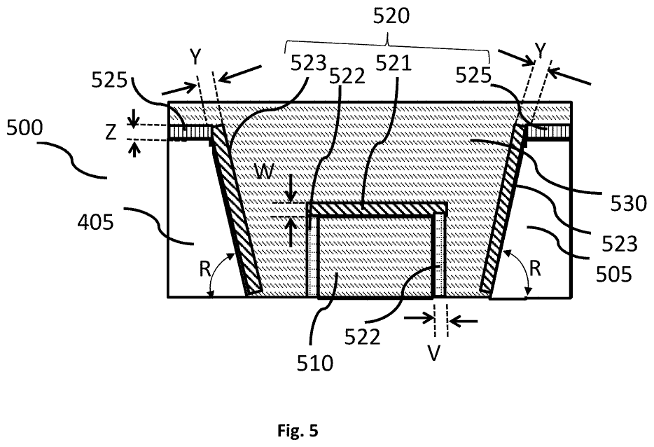

According to a preferred embodiment of the present invention, as shown in FIG. 5, a LED lamp 500 is disclosed. The LED lamp 500 comprises: at least one reflecting cup 505. At least one LED component 510 is disposed in the reflecting cup 505; The inclined surface of the reflecting cup 505 and the bottom end of the reflecting cup 505 included angle R is between 15 degrees and 80 degrees; and a fluorescent unit 520, which is the fluorescent unit 520 It is a mixed layer of fluorescent particles and adhesives. The fluorescent unit 520 further includes a top layer of LED component 521, a side layer of LED component 522, a surface layer of beveled reflecting cup 523, a surface layer of substrate body 524, and the surface layer of top reflecting cup 525; the top layer of LED component 521 is disposed on the side of LED component 510 away from the bottom end of the reflecting cup 505, and the thickness W of the top layer of LED component 521 is between 1 nanometer and 10 cm; the side layer of LED component 522 is disposed on the LED component 510 and the substrate body 501 is vertical, and the thickness V of the side layer of the LED component 522 is between 1 nanometer and 10 cm; the surface layer of beveled reflecting cup 523 is disposed on the inclined surface of the reflecting cup 505, and the thickness Y of the surface layer of beveled reflecting cup 523 is between 1 nanometer and 10 cm; the surface layer of top reflecting cup 525 is disposed on the top surface of the reflecting cup 505, and the thickness Z of the surface layer of top reflecting cup 525 is above 1 nanometer; Wherein, the combined thickness of the side layer of the LED component 522 and the surface layer of beveled reflecting cup 523 is smaller than the distance between the vertical surface of the LED component 510 and the bottom end surface of the reflecting cup 505 and the inclined surface of the reflecting cup 505; the surface layer of beveled reflecting cup 523 covers the inclined surface of the reflecting cup 505, Wherein, the fluorescent particles of the surface layer of beveled reflecting cup 523 cover the area of the inclined surface of the reflecting cup 505 by more than 50%; at least one package unit 530 is silicone that covers the LED component 510, the reflecting cup 505, and the fluorescent unit 520.

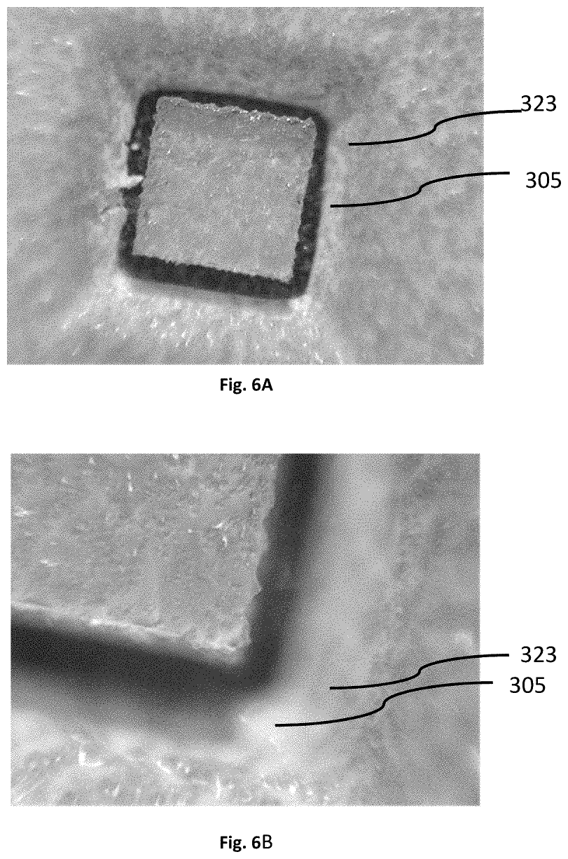

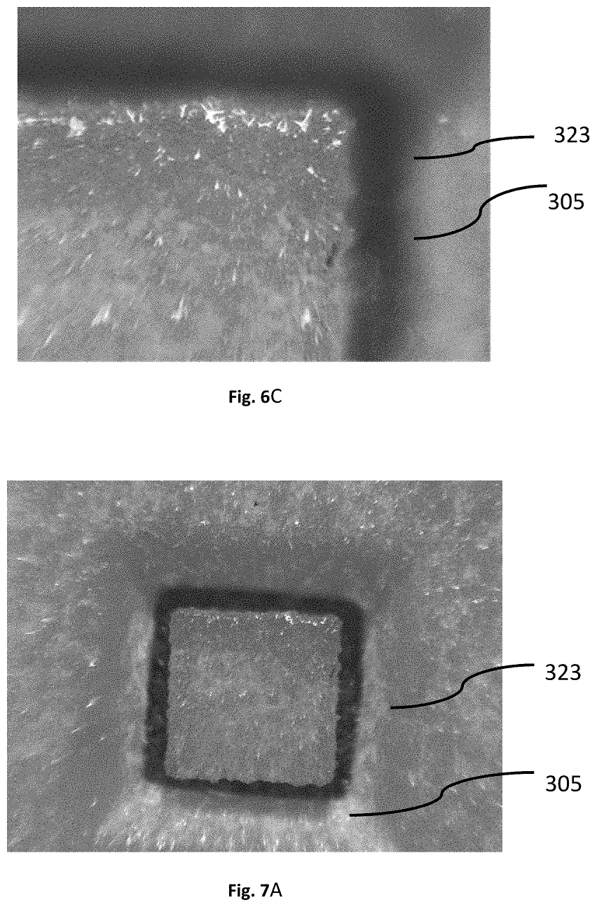

Referring to FIG. 6A, 6B, 6C, according to this embodiment, the part of the inclined surface of the reflecting cup 305 is not covered by fluorescent particles. The fluorescent particles of the surface layer of beveled reflecting cup 323 cover about 60% of the area of the inclined surface of the reflecting cup 305, and the thickness Y of the surface layer of beveled reflecting cup 323 is about 50 microns.

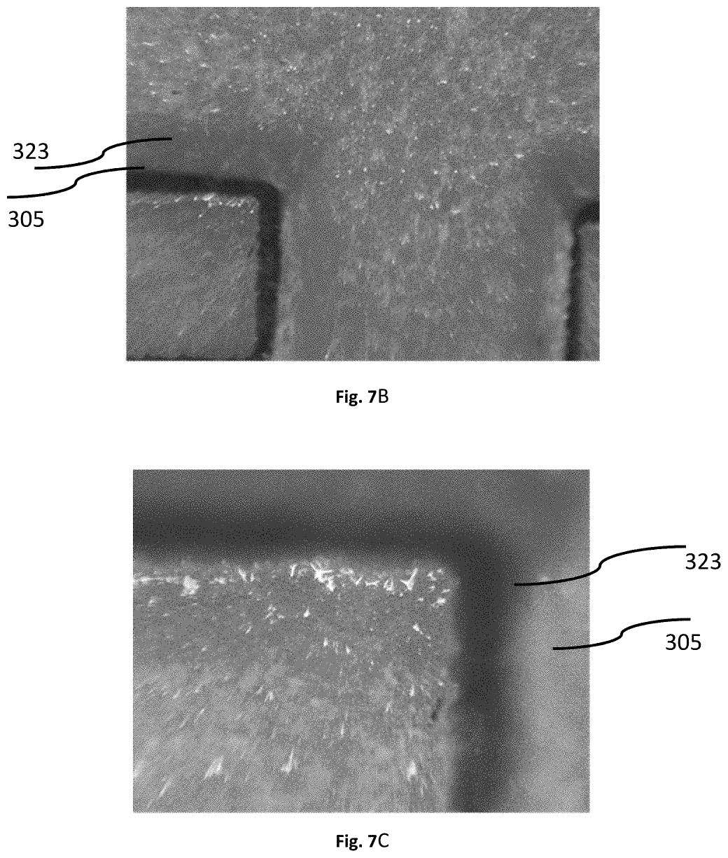

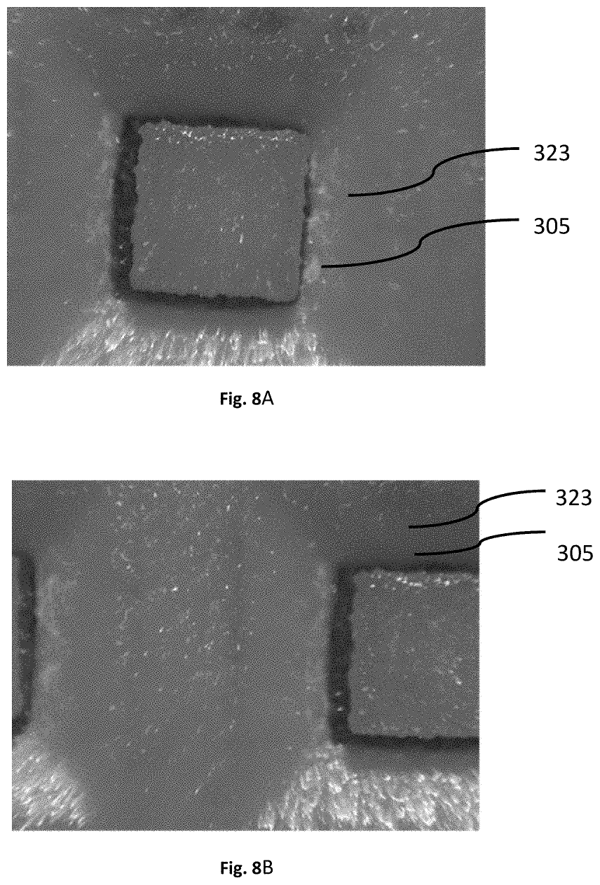

Referring to FIG. 7A, 7B, 7C, according to this embodiment, the part of the inclined surface of the reflecting cup 305 is not covered by fluorescent particles. The fluorescent particles of the surface layer of beveled reflecting cup 323 cover about 70% of the area of the inclined surface of the reflecting cup 305, and the thickness Y of the surface layer of beveled reflecting cup 323 is about 70 microns.

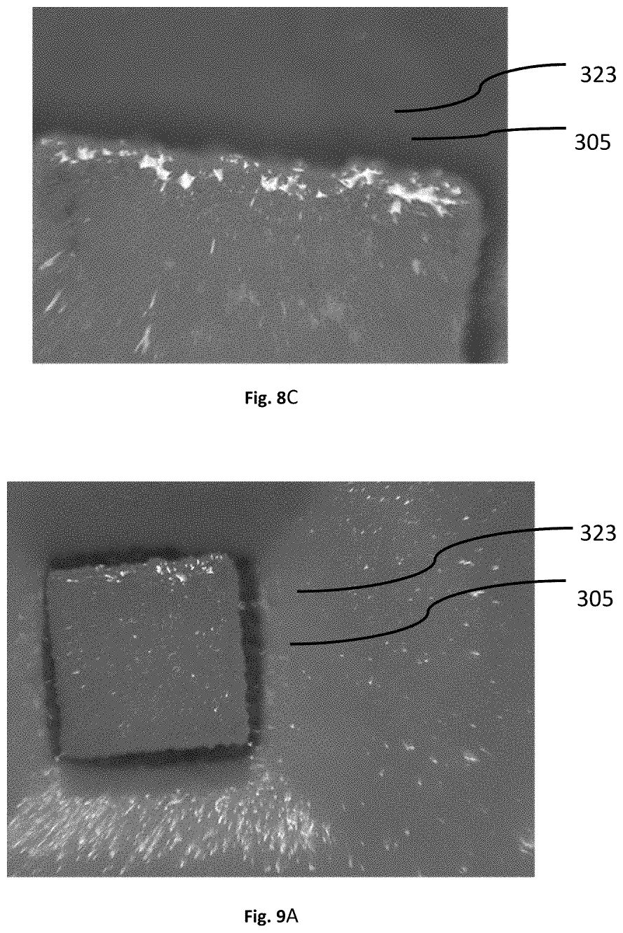

Referring to FIG. 8A, 8B, 8C, according to this embodiment, the part of the inclined surface of the reflecting cup 305 is not covered by fluorescent particles. The fluorescent particles of the surface layer of beveled reflecting cup 323 cover about 80% of the area of the inclined surface of the reflecting cup 305, and the thickness Y of the surface layer of beveled reflecting cup 323 is about 80 microns.

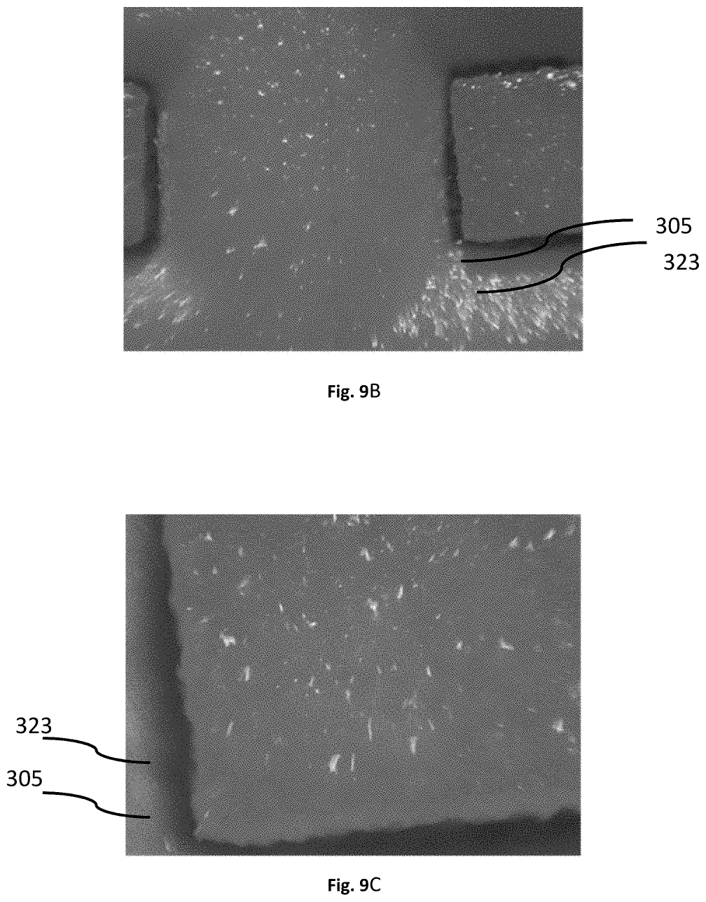

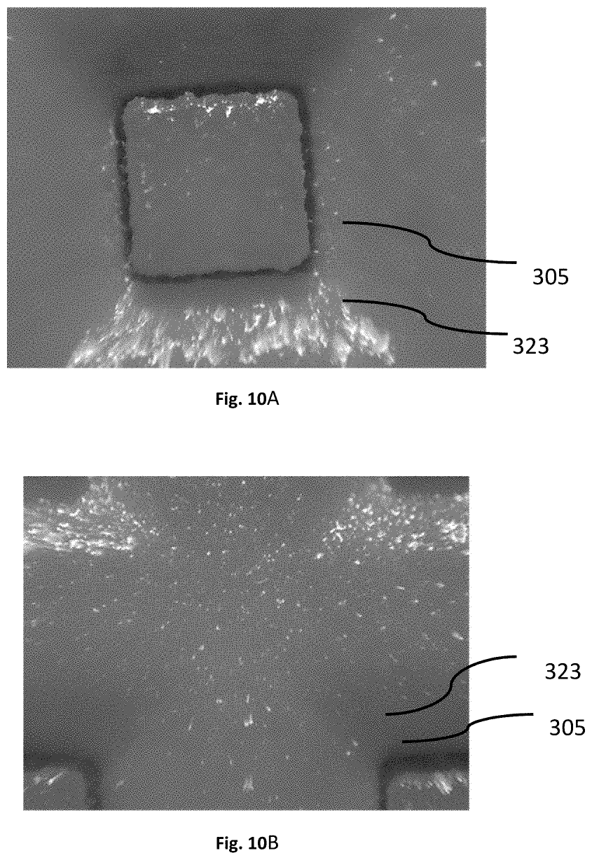

Referring to FIG. 9A, 9B, 9C, according to this embodiment, the part of the inclined surface of the reflecting cup 305 is not covered by fluorescent particles. The fluorescent particles of the surface layer of beveled reflecting cup 323 cover about 90% of the area of the inclined surface of the reflecting cup 305, and the thickness Y of the surface layer of beveled reflecting cup 323 is about 100 microns.

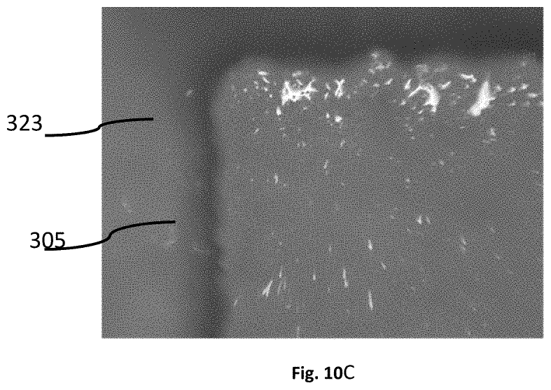

Referring to FIG. 10A, 10B, 10C, according to this embodiment, the part of the inclined surface of the reflecting cup 305 is not covered by fluorescent particles. The fluorescent particles of the surface layer of beveled reflecting cup 323 cover about 100% of the area of the inclined surface of the reflecting cup 305, and the thickness Y of the surface layer of beveled reflecting cup 323 is about 200 microns.

According to the above embodiment, the fluorescent particles of the surface layer of beveled reflecting cup 323 cover about 60% of the area of the inclined surface of the reflecting cup 305, and the thickness Y of the surface layer of beveled reflecting cup 323 is about 50 microns. At this time, it was tested with a spot power of 350 mA by the test equipment LED spectrum tester DP76 to get the color temperature is 20,000-30,000 K and the brightness is 147.8 Lm. In addition, it was tested by the large integrating sphere of the test equipment with a spot power of 1.08 W to get the color temperature is 15850 K and the brightness is 127 Lm. The fluorescent particles of the surface layer of beveled reflecting cup 323 cover about 70% to 100% of the area of the inclined surface of the reflector cup 305. The color temperature and brightness measurement results are shown in the following table:

| | | color | |
|---|---|---|---|
| | | temperature | brightness |
| | test equipment/spot power | (k) (CCT) | (Lm) |
| The fluorescent particles of the surface layer | DP76/350 mA | 20000~30000 | 147.8 |
| of beveled reflecting cup 323 cover about | the large integrating | 15850 | 127 |
| 60% of the area of the inclined surface of the | sphere/1.08 W | | |
| reflector cup 305 | | | |
| (thickness 50 um) | | | |
| The fluorescent particles of the surface layer | DP76/350 mA | 5783 | 184.1 |
| of beveled reflecting cup 323 cover about | the large integrating | 5733 | 147 |
| 70% of the area of the inclined surface of the | sphere/1.08 W | | |
| reflector cup 305 | | | |
| (thickness 70 um) | | | |
| The fluorescent particles of the surface layer | DP76/350 mA | 4666 | 201.1 |
| of beveled reflecting cup 323 cover about | the large integrating | 4633 | 158.9 |
| 80% of the area of the inclined surface of the | sphere/1.08 W | | |
| reflector cup 305 | | | |
| (thickness 80 um) | | | |
| The fluorescent particles of the surface layer | DP76/350 mA | 4360 | 205 |
| of beveled reflecting cup 323 cover about | the large integrating | 4347 | 158 |
| 90% of the area of the inclined surface of the | sphere/1.08 W | | |
| reflector cup 305 | | | |
| (thickness 100 um) | | | |
| The fluorescent particles of the surface layer | DP76/350 mA | 4075 | 231.3 |
| of beveled reflecting cup 323 cover about | the large integrating | 4013 | 166.9 |
| 100% of the area of the inclined surface of | sphere/1.08 W | | |
| the reflector cup 305 | | | |
| (thickness 200 um) | | | |

In addition, the fluorescent particles of the surface layer of beveled reflecting cup 323 cover less than 60% of the area of the inclined surface of the reflector cup 305. The color temperature is greater than 20,000 to 30,000 K when tested by the test device DP76 with a spot power of 350 mA, this example discussion.

Furthermore, the thickness Y of the surface layer of beveled reflecting cup 323 must be higher than the fluorescent reflective layer within 1 nanometer (nm) above the wafer to infinity, that is, from the surface of the substrate body 301 to the surface of the LED component 310 above 1 nanometer to infinite range distribution ratio. The thickness Y of the surface layer of beveled reflecting cup 323 is defined as 1 nm˜infinity, because as long as the phosphor particles cover the inclined surface of the reflecting cup 305 to 100%, the thickness Y of the inclined surface of the reflecting cup 305 does not affect the excitation brightness of the reflector. Only the thickness W of the top layer of LED component 321 on the surface of the LED component 310 will affect the color temperature change and brightness.

According to another object of the present invention, a method for increasing the lumens of the LED lamp 300 is provided. The method for increasing the lumens of the LED lamp 300 comprises: At least one reflecting cup 305 is provided. The reflecting cup 305 is disposed on the substrate body 301 and the inclined surface of the reflecting cup 305 and the substrate body 301 included angle R is between 15 degrees and 70 degrees; at least one LED component 310 is disposed on the substrate body 301 and is electrically connected to the substrate body 301; At least one fluorescent unit 320 is provided. The fluorescent unit 320 is a mixed layer of fluorescent particles and adhesives. The fluorescent unit 320 further includes a top layer of LED component 321, a side layer of LED component 322, a surface layer of beveled reflecting cup 323, and a surface layer of substrate body 324; the top layer of LED component 321 is disposed on the side of LED component 310 away from the substrate body 301, and the thickness W of the top layer of LED component 321 is between 1 nanometer and 10 cm; the side layer of LED component 322 is disposed on the LED component 310 and the substrate body 301 is vertical, and the thickness V of the side layer of the LED component 322 is between 1 nanometer and 10 cm; the surface layer of beveled reflecting cup 323 is disposed on the inclined surface of the reflecting cup 305, and the thickness Y of the surface layer of beveled reflecting cup 323 is above 1 nanometer; the surface layer of the substrate body 324 is disposed on the surface of the substrate body 301 between the LED component 310 and the reflecting cup 305, and the thickness U of the surface layer of substrate body 324 is between 1 nanometer and 10 cm; Wherein, the side layer of LED component 322 is not connected to the surface layer of beveled reflecting cup 323; wherein, the surface layer of substrate body 324 is not higher than the top layer of LED component 321; the surface layer of beveled reflecting cup 323 covers the inclined surface of the reflecting cup 305, Wherein, the fluorescent particles of the surface layer of beveled reflecting cup 323 cover the area of the inclined surface of the reflecting cup 305 by more than 50%; The LED element 310 is electrically driven to perform a self-luminescence process to generate self-luminescence; and the LED element 310 is subjected to a self-luminescence process to generate self-luminescence; and by self-luminescence and the fluorescent unit 320 to perform an excitation light process to generate excitation light.

What is claimed is:

1-13. (canceled)

14. A LED lamp, comprising:
a substrate body;
a reflecting cup, said reflecting cup is disposed on said substrate body and said inclined surface of said reflecting cup and said substrate body included angle R is between 15 degrees and 80 degrees;
a LED component, said LED component is disposed on said substrate body and is electrically connected to said substrate body; and
a fluorescent unit, said fluorescent unit is a mixed layer of fluorescent particles and adhesives, wherein said fluorescent unit further includes a top layer of LED component, a side layer of LED component, a surface layer of beveled reflecting cup, and a surface layer of substrate body;
said top layer of LED component is disposed on the side of said LED component away from the substrate body, and the thickness of said top layer of LED component is between 1 nanometer and 10 cm; said side layer of LED component is disposed on said LED component and said substrate body is vertical, and the thickness of said side layer of LED component is between 1 nanometer and 10 cm; said surface layer of beveled reflecting cup is disposed on the inclined surface of said reflecting cup, and the thickness of said surface layer of beveled reflecting cup is above 1 nanometer; said surface layer of said substrate body is disposed on the surface of said substrate body between said LED component and said reflecting cup, and the thickness of said surface layer of substrate body is between 1 nanometer and 10 cm; wherein, the combined thickness of said side layer of LED component and said surface layer of beveled reflecting cup is smaller than the distance between the vertical surface of said LED component and said substrate body and the inclined surface of the reflecting cup; Wherein, said surface layer of substrate body is smaller than the distance between the side of said LED component away from said substrate body and the surface of said substrate body; said surface layer of beveled reflecting cup covers the inclined surface of said reflecting cup, wherein, the fluorescent particles of said surface layer of beveled reflecting cup cover the area of the inclined surface of said reflecting cup by more than 50%.

15. The LED lamp as claimed in claim 14, wherein said adhesives further includes Epoxy resin, silicone, wax, paraffin hydrocarbon, ceramic powder, graphene and glass powder.

16. The LED lamp as claimed in claim 14, wherein the thickness of top layer of LED component is between 1 nanometer and 1 cm.

17. The LED lamp as claimed in claim 14, wherein the thickness of side layer of LED component is between 1 nanometer and 1 cm.

18. The LED lamp as claimed in claim 14, wherein the thickness of said surface layer of beveled reflecting cup is between 1 nanometer and 1 cm.

19. The LED lamp as claimed in claim 14, wherein the thickness of said surface layer of substrate body is between 1 nanometer and 1 cm.

20. The LED lamp as claimed in claim 14, wherein the inclined surface of said reflecting cup and said substrate body included angle R is between 30 degrees and 60 degrees.

21. The LED lamp as claimed in claim 14, wherein the fluorescent particles of said surface layer of beveled reflecting cup cover the area of the inclined surface of said reflecting cup by more than 65%.

22. The LED lamp as claimed in claim 14, wherein the thickness of surface layer of substrate body is less than the thickness of top layer of LED component.

23. A LED lamp, comprising:
a substrate body;
a reflecting cup, said reflecting cup is disposed on said substrate body and said inclined surface of said reflecting cup and said substrate body included angle R is between 15 degrees and 80 degrees;
a LED component, said LED component is disposed on said substrate body and is electrically connected to said substrate body; and
a fluorescent unit, said fluorescent unit is a mixed layer of fluorescent particles and adhesives, wherein said fluorescent unit further includes a top layer of LED component, a side layer of LED component, a surface layer of beveled reflecting cup, a surface layer of substrate body, and the surface layer of top reflecting cup; said top layer of LED component is disposed on the side of said LED component away from the substrate body, and the thickness of said top layer of LED component is between 1 nanometer and 10 cm; said side layer of LED component is disposed on said LED component and said substrate body is vertical, and the thickness of said side layer of LED component is between 1 nanometer and 10 cm; said surface layer of beveled reflecting cup is disposed on the inclined surface of said reflecting cup, and the thickness of said surface layer of beveled reflecting cup is above 1 nanometer; said surface layer of said substrate body is disposed on the surface of said substrate body between said LED component and said reflecting cup, and the thickness of said surface layer of substrate body is between 1 nanometer and 10 cm; the surface layer of top reflecting cup is disposed on the top of the reflecting cup, and the thickness of the surface layer of top reflecting cup is above 1 nanometer; wherein, the combined thickness of said side layer of LED component and said surface layer of beveled reflecting cup is smaller than the distance between the vertical surface of said LED component and said substrate body and the inclined surface of the reflecting cup; Wherein, said surface layer of substrate body is smaller than the distance between the side of said LED component away from said substrate body and the surface of said substrate body; said surface layer of beveled reflecting cup covers the inclined surface of said reflecting cup, wherein, the fluorescent particles of said surface layer of beveled reflecting cup cover the area of the inclined surface of said reflecting cup by more than 50%.

24. The LED lamp as claimed in claim 23, wherein said adhesives further includes Epoxy resin, silicone, wax, paraffin hydrocarbon, ceramic powder, graphene and glass powder.

25. The LED lamp as claimed in claim 23, wherein the thickness of top layer of LED component is between 1 nanometer and 1 cm.

26. The LED lamp as claimed in claim 23, wherein the thickness of side layer of LED component is between 1 nanometer and 1 cm.

27. The LED lamp as claimed in claim 23, wherein the thickness of said surface layer of beveled reflecting cup is between 1 nanometer and 1 cm.

28. The LED lamp as claimed in claim 23, wherein the thickness of said surface layer of substrate body is between 1 nanometer and 1 cm.

29. The LED lamp as claimed in claim 23, wherein the inclined surface of said reflecting cup and said substrate body included angle R is between 30 degrees and 60 degrees.

30. The LED lamp as claimed in claim 23, wherein the fluorescent particles of said surface layer of beveled reflecting cup cover the area of the inclined surface of said reflecting cup by more than 65%.

31. The LED lamp as claimed in claim 23, wherein the thickness of surface layer of substrate body is less than the thickness of top layer of LED component.

32. The LED lamp as claimed in claim 23, wherein the thickness of said surface layer of top reflecting cup is above 1.

33. A LED lamp, comprising:
a reflecting cup;
a LED component, said reflecting cup is disposed on said substrate body and said inclined surface of said reflecting cup and the bottom end of the reflecting cup included angle R is between 15 degrees and 80 degrees;
a fluorescent unit, said fluorescent unit is a mixed layer of fluorescent particles and adhesives, wherein said fluorescent unit further includes a top layer of LED component, a side layer of LED component, a surface layer of beveled reflecting cup, and the surface layer of top reflecting cup; said top layer of LED component is disposed on the side of said LED component away from the bottom end of the reflecting cup, and the thickness of said top layer of LED component is between 1 nanometer and 10 cm; said side layer of LED component is disposed on said LED component and said substrate body is vertical, and the thickness of said side layer of LED component is between 1 nanometer and 10 cm; said surface layer of beveled reflecting cup is disposed on the inclined surface of said reflecting cup, and the thickness of said surface layer of beveled reflecting cup is above 1 nanometer; the surface layer of top reflecting cup is disposed on the top of the reflecting cup, and the thickness of the surface layer of top reflecting cup is above 1 nanometer; wherein, the combined thickness of said side layer of LED component and said surface layer of beveled reflecting cup is smaller than the distance between the vertical surface of said LED component and the bottom end of the reflecting cup and the inclined surface of the reflecting cup; wherein, said surface layer of substrate body is smaller than the distance between the side of said LED component away from said substrate body and the surface of said substrate body; said surface layer of beveled reflecting cup covers the inclined surface of said reflecting cup, wherein, the fluorescent particles of said surface layer of beveled reflecting cup cover the area of the inclined surface of said reflecting cup by more than 50%; and
a package unit, said package unit is silicone and covers said LED component, said reflecting cup, and said fluorescent unit.

34. The LED lamp as claimed in claim 33, wherein said adhesives further includes Epoxy resin, silicone, wax, paraffin hydrocarbon, ceramic powder, graphene and glass powder.

35. The LED lamp as claimed in claim 33, wherein the thickness of top layer of LED component is between 1 nanometer and 1 cm.

36. The LED lamp as claimed in claim 33, wherein the thickness of side layer of LED component is between 1 nanometer and 1 cm.

37. The LED lamp as claimed in claim 33, wherein the thickness of said surface layer of beveled reflecting cup is between 1 nanometer and 1 cm.

38. The LED lamp as claimed in claim 33, wherein the inclined surface of said reflecting cup and said substrate body included angle R is between 30 degrees and 60 degrees.

39. The LED lamp as claimed in claim 33, wherein the fluorescent particles of said surface layer of beveled reflecting cup cover the area of the inclined surface of said reflecting cup by more than 65%.

40. The LED lamp as claimed in claim 33, wherein the thickness of surface layer of substrate body is less than the thickness of top layer of LED component.

41. A method for increasing the lumens of the LED lamp, comprising:
providing a reflecting cup, said reflecting cup is disposed on a substrate body and said inclined surface of said reflecting cup and said substrate body included angle R is between 15 degrees and 80 degrees; a LED component, said LED component is disposed on the substrate body and is electrically connected to said substrate body; and
providing a fluorescent unit, said fluorescent unit is a mixed layer of fluorescent particles and adhesives, wherein said fluorescent unit further includes a top layer of LED component, a side layer of LED component, a surface layer of beveled reflecting cup, and a surface layer of substrate body;
said top layer of LED component is disposed on the side of said LED component away from the substrate body, and the thickness of said top layer of LED component is between 1 nanometer and 10 cm; said side layer of LED component is disposed on said LED component and said substrate body is vertical, and the thickness of said side layer of LED component is between 1 nanometer and 10 cm; said surface layer of beveled reflecting cup is disposed on the inclined surface of said reflecting cup, and the thickness of said surface layer of beveled reflecting cup is between 1 nanometer and 10 cm; said surface layer of said substrate body is disposed on the surface of said substrate body between said LED component and said reflecting cup, and the thickness of said surface layer of substrate body is between 1 nanometer and 10 cm; wherein, the combined thickness of said side layer of LED component and said surface layer of beveled reflecting cup is smaller than the distance between the vertical surface of said LED component and said substrate body and the inclined surface of the reflecting cup; wherein, said surface layer of substrate body is smaller than the distance between the side of said LED component away from said substrate body and the surface of said substrate body; said surface layer of beveled reflecting cup covers the inclined surface of said reflecting cup, wherein, the fluorescent particles of said surface layer of beveled reflecting cup cover the area of the inclined surface of said reflecting cup by more than 50%;
performing a self-luminous process, in order to the LED element is driven to generate self-luminescence by electrical driving; and
performing an excitation by the self-luminous and the fluorescent unit light process, in order to generate excitation light.

42. The LED lamp as claimed in claim 41, wherein the thickness of top layer of LED component is between 1 nanometer and 1 cm.

43. The LED lamp as claimed in claim 41, wherein the thickness of side layer of LED component is between 1 nanometer and 1 cm.

44. The LED lamp as claimed in claim 41, wherein the thickness of said surface layer of beveled reflecting cup is between 1 nanometer and 1 cm.

45. The LED lamp as claimed in claim 41, wherein the thickness of said surface layer of substrate body is between 1 nanometer and 1 cm.

46. The LED lamp as claimed in claim 41, wherein the inclined surface of said reflecting cup and said substrate body included angle R is between 30 degrees and 60 degrees.

47. The LED lamp as claimed in claim 41, wherein the fluorescent particles of said surface layer of beveled reflecting cup cover the area of the inclined surface of said reflecting cup by more than 65%.

48. The LED lamp as claimed in claim 41, wherein the thickness of surface layer of substrate body is less than the thickness of top layer of LED component.
